(19) United States
(12) Patent Application Publication
(10) Pub. No.: US 2007/0141846 A1
(43) Pub. Date: Jun. 21, 2007

(54) Rapid thermal processing system

(76) Inventor: Won Sik Nam, Hwaseong-si (KR)

Correspondence Address: IPLA P.A., 3580 WILSHIRE BLVD., 17TH FLOOR, LOS ANGELES, CA, 90010, US

(21) Appl. No.: 10/595,994

(22) PCT Filed: Aug. 26, 2004
(86) PCT No.: PCT/KR04/02140

§ 371 Date: May 24, 2006

(30) Foreign Application Priority Data
Nov. 24, 2003 (KR) 10-2003-0083692

(51) Int. Cl. H01L 21/311; C23C 16/00

(52) U.S. Cl. 438/703; 118/724

(57) ABSTRACT

Disclosed herein is a rapid thermal processing system. The rapid thermal processing system comprises a chamber having an inner surface with a cross-section in a multi-line shape consisting of a plurality of arcs separated from each other while having the same radius and the center, and a plurality of lines connecting the arcs. The chamber overcomes disadvantages of a conventional circular-shaped chamber and the square-shaped chamber. Furthermore, a quartz window has an outer peripheral surface consisting of a combination of a tilt surface, a perpendicular surface, and a round surface, so that even though the quartz window is mounted on the chamber in an inversed state, sealing between the chamber and the quartz window can be maintained. Components of an edge ring are connected by means of a double connecting structure, thereby ensuring a high resistance against thermal deformation compared with the prior art. Additionally, the rapid thermal processing system is provided with independent cooling systems for respective components thereof, allowing effective temperature control for the respective components.

### TECHNICAL FIELD

The present invention relates to a rapid thermal processing system, and more particularly to a rapid thermal processing system, in which respective components have an enhanced structure and employ independent cooling systems, respectively.

### BACKGROUND ART

As for a representative example of heat treatment equipment for a wafer, there is a rapid thermal processing system, which is used for performing processes, such as rapid thermal annealing, rapid thermal cleaning, rapid thermal chemical vapor deposition, rapid thermal oxidation, and rapid thermal nitration. In the rapid thermal processing system, since heating and cooling of the wafer are performed in a wide range of temperatures within a very short time, there is a requirement for accurate temperature control. Additionally, since the processes in the rapid thermal processing system are rapidly carried out at a remarkably high temperature, not only a rapid and uniform heat transmission, but a rapid and uniform cooling is also very important. At this time, since results of the processes may vary according to the disposition of a heat source, the shape of a chamber, and peripheral apparatuses of the whole system, the arrangement of the heat source, the shape of the chamber, and the peripheral apparatuses must be investigated. Particularly, the shape of the chamber is an important factor in effective distribution of ultraviolet rays emitted from the heat source and maintenance of the distributed shape of the ultraviolet rays. Accordingly, as for the most important factor to maintain optimal conditions for the processes, it must be considered whether the chamber has a stable configuration in association with the heat source. With regard to this, the idealistic shape of the chamber is the same as the disposition of the heat source. However, due to several peripheral apparatuses required for the processes, it is difficult for the chamber to have the same shape as the disposition of the heat source. Next, it must be determined whether rapid cooling as well as rapid heating can be performed in the system. Additionally, an appropriate arrangement of the components constituting the chamber must be considered. Generally, the rapid thermal processing system is manufactured after obtaining an experimental or theoretical basis using simulation or scaled versions of the rapid thermal processing system manufactured according to these considerations.

Generally, the chamber is manufactured to have the same shape as the arrangement structure of the heat sources, which can be classified into a square shape and a circular shape.

FIG. 1 is a schematic diagram illustrating a square-shaped chamber, which is a chamber generally used when employing a bar-shaped tungsten halogen lamp as a heat source, and FIG. 2 is a schematic diagram illustrating a circular-shaped chamber, which is a chamber generally used when employing a vertical bulb-shaped tungsten halogen lamp as a heat source.

Referring to FIGS. 1 and 2, a chamber 10 is provided, on the bottom 11 thereof, with a temperature measurement sensor 40, an edge ring 50 for mounting a wafer, and a quartz pin 60, and on lateral walls of the chamber 10, with a gas injection port 12 and a gas exhaust port 13. Furthermore, the chamber 10 is provided therein with a heat source 21 or 22 and a quartz window 30 for effective transmission of the ultraviolet rays emitted from the heat source.

As shown in FIG. 1, the chamber 10 employing the bar-shaped tungsten halogen lamp 21 has a merit of simplifying the configuration of the chamber 10 and of a mounting portion of the temperature measurement sensor 40. This is attributed to the fact that one lamp applies heat to a wide range, so that the number of the temperature measurement sensors 40 can be reduced. However, the chamber 10 employing the bar-shaped tungsten halogen lamp 21 has a disadvantage in that accurate control of the temperature cannot be achieved.

Meanwhile, among the chambers classified according to the shape of the chamber, the square-shaped chamber has a disadvantage of non-uniform temperature at the corners of the chamber. This is attributed to the fact that since an object to be heat treated in the chamber 10 is a circular plate-shaped wafer, it is difficult to control the temperature at corners of the square-shaped chamber. Furthermore, the square-shaped chamber has a disadvantage in that it is difficult to maintain a uniform flow of the gas. This is attributed to the fact that, in order to maintain the uniform flow of the gas in the square-shaped chamber, gas supply nozzles must be aligned in a line along one wall of the square-shaped chamber, and the gas must be uniformly injected through all nozzles. For this purpose, every gas supply nozzle must be increased in diameter of an injection end thereof. Meanwhile, since the gas supply nozzles are exposed to a remarkably high temperature, the gas supply nozzles are made of quartz or a material having a thermal resistance close to that of quartz, so that thermal radiation efficiency is lowered in the region where the gas supply nozzles is formed. Accordingly, the injection end of each gas supply nozzle is positioned coplanar to an inner surface of the chamber, minimizing exposure of the gas supply nozzles.

Furthermore, since the gas exhaust port must be positioned along another lateral wall of the square-shaped chamber in the horizontal direction, like the gas supply nozzles, in order to maintain the uniform flow of the gas at the gas exhaust port, the thermal radiation efficiency is lowered in the region where the gas exhaust port is formed, thereby reducing the uniformity of the temperature.

Meanwhile, among the main processes in the rapid thermal processing, rapid thermal annealing and rapid thermal nitration are required to control the concentration of oxygen. Since higher concentrations of oxygen have a negative influence on the results of the processes, the concentration of oxygen is lowered by means of nitrogen gas, ammonia gas or argon gas. With regard to this, since the flow of the gas may be stagnated or become a vortex current at the corners of the square-shaped chamber, productivity is directly related to the control of the flow of the gas. Thus, the configuration of the chamber is particularly important.

Furthermore, the thickness of the quartz window must be lowered to enhance the thermal efficiency, while having a remarkably high intensity of illumination on the surface to enhance the permeability. However, since the quartz window of the square-shaped chamber also has a square shape, the fracture center caused by loads applied to the quartz window is also positioned at the center of the quartz window, and as the thickness of the quartz window is lowered, the quartz window can be more easily fractured by a small variation in pressure. Accordingly, when designing a supporting member of the quartz window or calculating the thickness thereof, considerable attention must be paid thereto.

When the chamber 10 employs the vertical bulb-shaped tungsten halogen lamp 22 as shown in FIG. 2, there is a problem in that the configuration of the chamber is more complicated than that of the chamber shown in FIG. 1. This is attributed to the fact that since the vertical bulb-shaped tungsten halogen lamp 22 heats local sections and has negative thermal efficiency, a number of lamps 22 and temperature measurement sensors 40 are required. On the contrary, it has an advantage in that the temperature can be accurately controlled. The chamber employing the heat source like the vertical bulb-shaped tungsten halogen lamp 22 generally has a circular shape.

The circular-shaped chamber has many advantages when compared with the square-shaped chamber. First, since the circular-shaped chamber has the same shape as that of the wafer, the uniformity of the temperature can be enhanced. This is attributed to the fact that the secondary thermal radiation emitted from the surface of the chamber is uniformly applied to the surface of the wafer. Second, in terms of the gas flow, the stagnation of the gas and the vortex current occur less in the circular-shaped chamber than in the circular-shaped chamber. Third, since the quartz window of the circular-shaped chamber also has a circular shape, the quartz window of the circular-shaped chamber has a thickness lower than the thickness of the square-shaped chamber, and is less sensitive to the variation in pressure than the square-shaped chamber. Accordingly, there is more freedom in the design of the circular-shaped chamber. Furthermore, when machining an inner surface of the circular-shaped chamber, variation caused by the machining is remarkable, thereby having a significant influence on the processes. However, the configuration of the gas nozzle having a circular shape appropriate to the circular-shaped chamber becomes very complicated. That is, as shown in FIG. 2, the circular-shaped chamber 10 has different cross-sectional areas at an upper layer, a middle layer, and a lower layer, respectively, and thus, it must be manufactured such that the gas may flow in a wave shape. This requires considerable manufacturing costs and time. As a result, in order to obtain the gas flow in the wave shape, a method of rotating the wafer is adopted. By rotating the wafer, some advantages are obtained. For instance, the uniformity of temperature is enhanced, and a uniform gas flow is obtained on the surface of the wafer only with a single gas nozzle. However, since the regions provided with a wafer feeding passage and with the gas exhaust port constitute passages therein, the radiation heat cannot be obtained in these regions, and the uniformity of the temperature is thus reduced.

As described above, since the conventional chambers and heat sources have merits and disadvantages contrary to each other, an optimum design of the chamber and heat source is required to provide optimum rapid thermal processing.

### DISCLOSURE

### Technical Problem

Therefore, the present invention has been made in view of the above problems, and it is an object of the present invention to provide a rapid thermal processing system having a chamber designed to overcome the problems of the conventional chamber.

It is another object of the invention to provide a rapid thermal processing system designed to prevent thermal deformation of respective components and to allow effective temperature control.

### TECHNICAL SOLUTION

In accordance with an aspect of the present invention, the above and other objects can be accomplished by the provision of a rapid thermal processing system, comprising: a chamber provided at a lateral wall of the chamber with one or more processing gas injection ports and at the opposite lateral wall thereof with one or more processing gas exhaust ports; a heat source installed in the chamber for heating a wafer; a quartz window mounted on the chamber such that the quartz window can be located below the heat source; an edge ring-support installed in the chamber such that edge ring-support can be located below the quartz window; and an edge ring installed on the edge ring-support for mounting the wafer, wherein the chamber has an inner surface with a cross-section in a multi-line shape consisting of a plurality of arcs separated from each other and having the same radius and the same center, and a plurality of straight lines connecting the arcs to each other.

Each of the arcs may have a central angle of 15-50°.

The quartz window may have an outer peripheral surface consisting of a combination of a tilt surface, a perpendicular surface, and a round surface. The quartz window may have an area larger than that of the inner surface of the chamber, and a square shape having edges, each opposing the straight line portion of the inner surface of the chamber while being positioned at the outside of the straight line portion; and the rapid thermal processing system may further comprise one or more cooling water jackets, each being installed in the chamber such that the cooling water jacket can be positioned at a lower portion of a region defined between the edge of the quartz window and the straight line portion of the inner surface of the chamber.

The edge ring-support may comprise: a rotational member installed in the chamber and having a rotational wing with a groove formed on an upper surface of the rotational wing; a cylinder connected to the rotational wing and mounting the edge ring on an upper surface of the cylinder; a cylinder guide engaged with the cylinder; and a cylinder guide-fixing pin for fixing the cylinder guide to the rotational wing.

The rapid thermal processing system may further comprise a cooling/heating water-circulation passage provided in an inner wall of the chamber such that the circulation passage surrounds an outer peripheral surface of the edge ring and a predetermined area of the edge ring-support. Furthermore, the rapid thermal processing system may further comprise a first cooling gas injection part for injecting a cooling gas into the chamber, and a first cooling gas exhaust part for exhausting the cooling gas exhausted from the first cooling gas injection part to the outside of the chamber, the first cooling gas injection part and the first cooling gas exhaust part being installed on the bottom surface of the chamber. Furthermore, the rapid thermal processing system may further comprise a second cooling gas injection part, formed on the lateral wall of the chamber while being spaced from the processing gas injection ports, for injecting the cooling gas over the wafer mounted on the edge ring, the second cooling gas injection part having an injection end with a gentle slope formed at a predetermined region of the injection end, such that some portions of the cooling gas being injected can flow along the lateral wall of the chamber, and with a steep slope formed at a rest region of the injection end. Furthermore, the cooling/heating water-circulation passage may have a groove formed around an outer surface of the cooling/heating water-circulation passage facing the inner wall of the chamber, and the rapid thermal processing system may further comprise a third cooling gas injection part and a third cooling gas exhaust part installed in the chamber while being communicated with the groove, respectively.

### ADVANTAGEOUS EFFECTS

As is apparent from the description, according to the rapid thermal processing system, a chamber has an inner surface having a cross section of a multi-line shape consisting of a plurality of arcs separated from each other while having the same radius, and the same center, and a plurality of straight lines connecting the arcs to each other, thereby overcoming the disadvantages of the conventional rapid thermal processing system while maintaining the merits of the conventional rapid thermal processing system.

Furthermore, a quartz window has an outer peripheral surface consisting of a combination of a tilt surface, a perpendicular surface, and a round surface, so that even though the quartz window is mounted on the chamber in an inversed state, sealing between the chamber and the quartz window can be maintained by means of an O-ring.

Additionally, components of an edge ring are connected by means of a double connecting structure, thereby ensuring a high resistance against thermal deformation.

Furthermore, the rapid thermal processing system of the present invention is provided with independent cooling systems for cooling an upper portion of the chamber, a lower portion of the chamber, the quartz window, the edge ring, and an edge ring-support, respectively, thereby allowing effective temperature control for the respective components constituting the rapid thermal processing system.

It should be noted that the present invention is not limited to the embodiment, and that the present invention can be modified by a person of ordinary skill in the art within the spirit of the present invention.

### DESCRIPTION OF THE DRAWINGS

The above and other objects, features and other advantages of the present invention will be more clearly understood from the following detailed description taken in conjunction with the accompanying drawings, in which:

FIGS. 1 and 2 are schematic diagrams illustrating a conventional rapid thermal processing system;

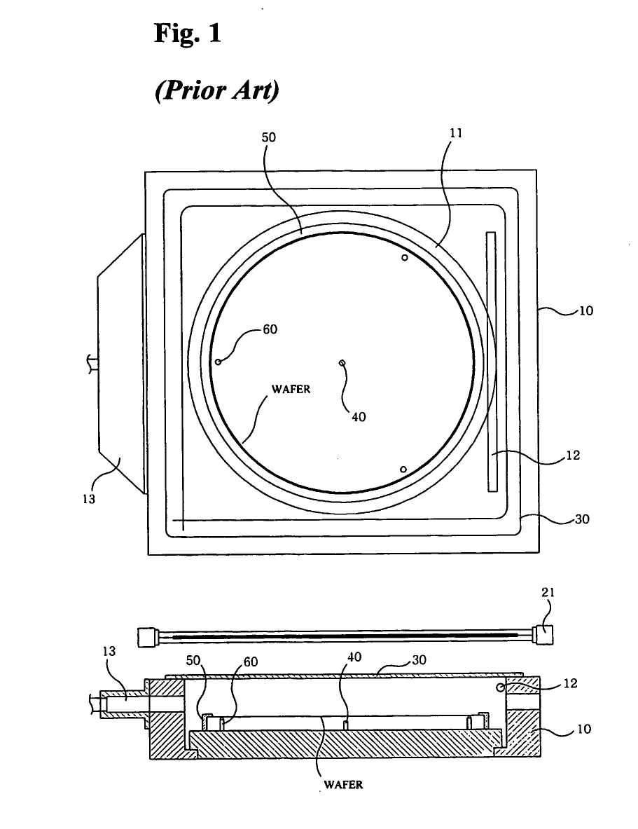

FIG. 3 is a schematic diagram illustrating a rapid thermal processing system according to one embodiment of the present invention;

FIG. 4 is a cross-sectional view of the rapid thermal processing system taken along line a-b of FIG. 3;

FIG. 5 is a cross-sectional view of the rapid thermal processing system taken along line c-d of FIG. 3;

FIG. 6 is a cross-sectional view of the rapid thermal processing system taken along line e-e of FIG. 3;

FIG. 7 is an enlarged view of the rapid thermal processing system at a portion ‘A’ of FIG. 4;

FIG. 8 is a cross-sectional view of the rapid thermal processing system taken along line f-f of FIG. 3; and

FIG. 9 is an enlarged view of the rapid thermal processing system at a portion ‘B’ of FIG. 4.

### BEST MODE

Preferred embodiments of the present invention will be described in detail with reference to the drawings.

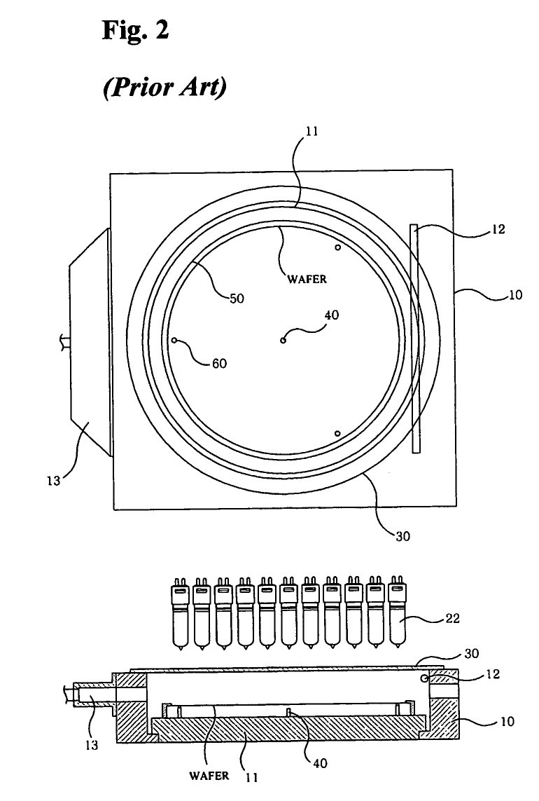

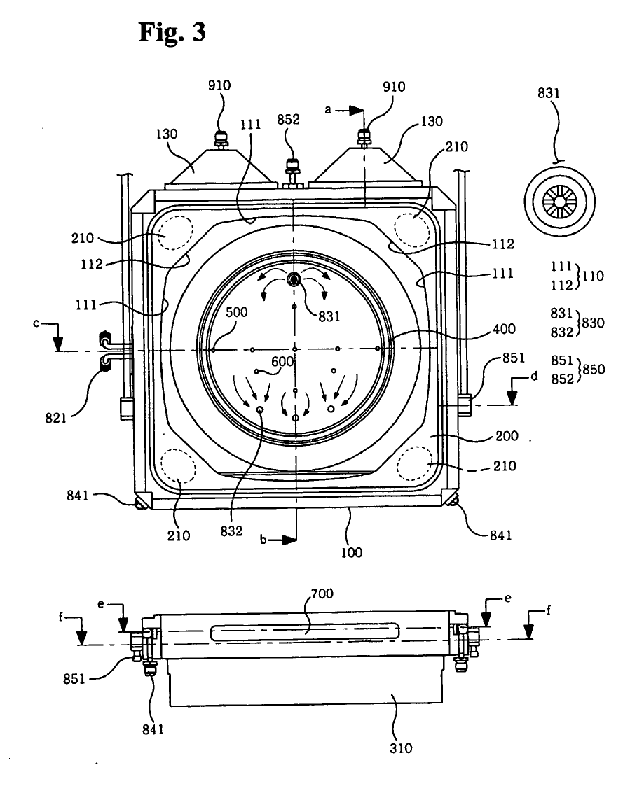

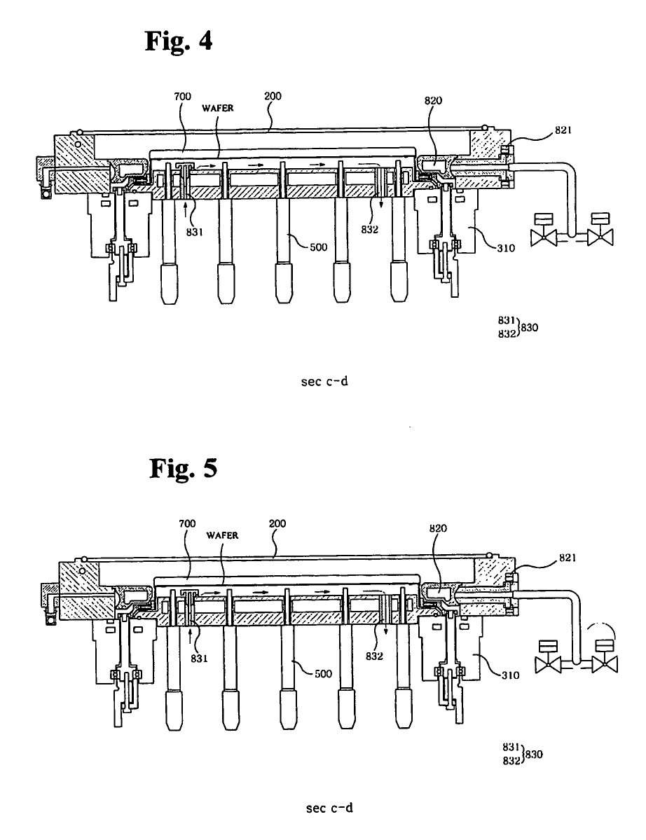

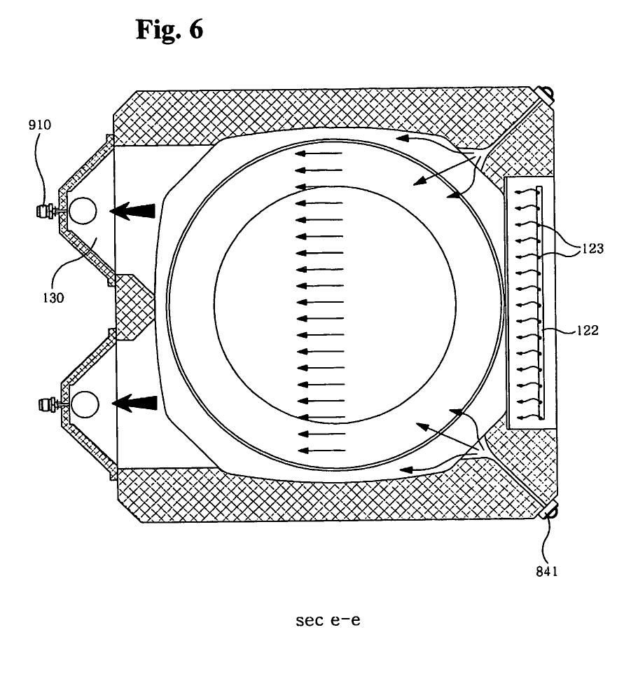

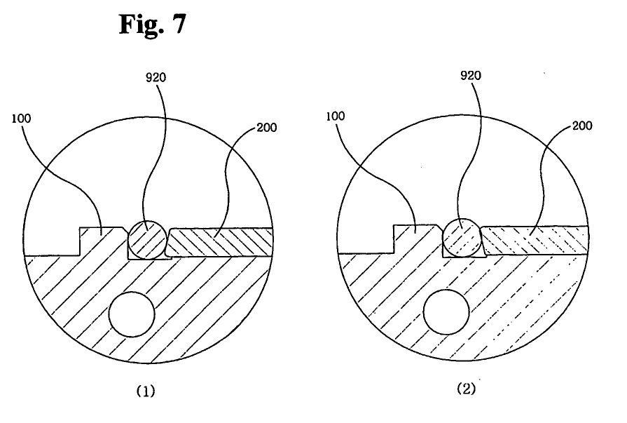

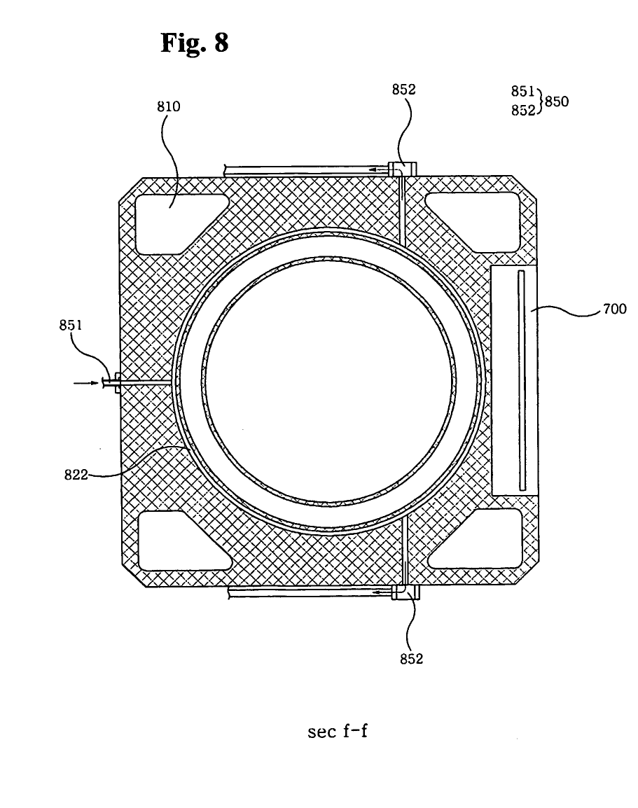

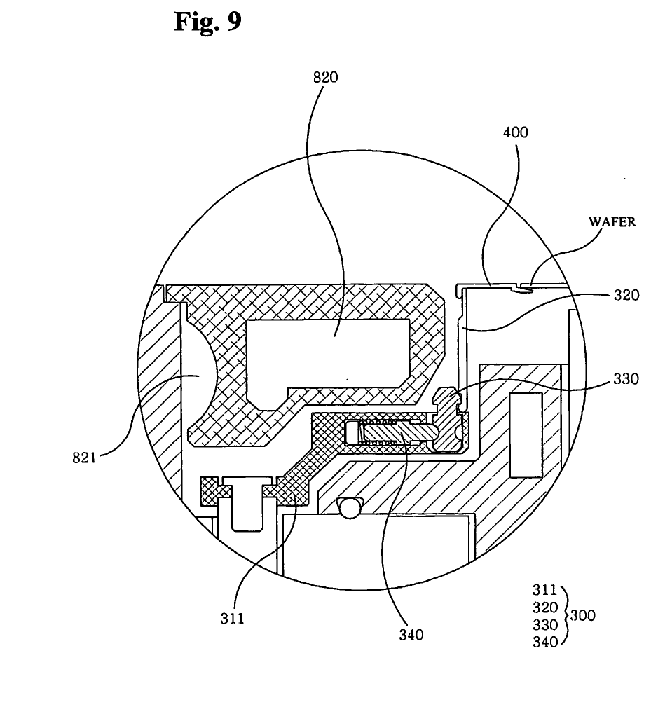

FIG. 3 is a schematic diagram illustrating a rapid thermal processing system according to one embodiment of the present invention. FIG. 4 is a cross-sectional view of the rapid thermal processing system taken along line a-b of FIG. 3. FIG. 5 is a cross-sectional view of the rapid thermal processing system taken along line c-d of FIG. 3. FIG. 6 is a cross-sectional view of the rapid thermal processing system taken along line e-e of FIG. 3. FIG. 7 is an enlarged view of the rapid thermal processing system at a portion ‘A’ of FIG. 4. FIG. 8 is a cross-sectional view of the rapid thermal processing system taken along line f-f of FIG. 3. FIG. 9 is an enlarged view of the rapid thermal processing system at a portion ‘B’ of FIG. 4.

Referring to FIGS. 3 to 5, a rapid thermal processing system according to one embodiment of the present invention comprises a chamber 100 provided with one or more processing gas injection ports 123 and one or more processing gas exhaust ports 130; a heat source (not shown) installed in the chamber to heat a wafer; a quartz window 200 mounted on the chamber 100 to be located below the heat source; an edge ring-support 300 installed in the chamber to be located below the quartz window 200; temperature measurement sensor 500; a wafer lift pin 600; a wafer feeding passage 700; various cooling systems; and an edge ring 400 installed on the edge ring-support 300 for mounting the wafer.

Referring to FIG. 3, the chamber 100 has an inner surface 110 having a cross section of a multi-line shape consisting of a plurality of arcs 111 separated from each other while having the same radius and the same center, and a plurality of straight lines 112 connecting the arcs to each other. Here, each of the arcs 111 has a central angle defined such that a tangential angle defined by the straight line 112 and the arc 111 at a contact point between the straight line 112 and the arc 111 is an obtuse angle. According to the present embodiment, four arcs 111, each of which has the central angle of 15-50′, oppose each other at the right and left sides, and at the front and rear sides of the chamber, respectively, and four straight lines 112 oppose each other in the diagonal direction. It is apparent that the number of arcs 111, the number of straight lines 112, and the central angle of the arc 112 can be variously modified. Accordingly, the chamber according to the embodiment of the invention can overcome the disadvantages of the conventional chamber while maintaining the merits thereof.

Referring to FIGS. 3, 4, and 6, the processing gas injection ports 123 are installed on a lateral wall of the chamber 100 and the processing gas exhaust ports 130 are installed on the opposite lateral wall thereof. The processing gas injection ports 123 and the processing gas exhaust ports 130 are installed in the chamber 100 such that respective imaginary lines connecting the center of the processing gas injection ports 123 to the center of the processing gas injection ports 123 are positioned over the wafer so that processing gas flows at a height at which the wafer is mounted in the chamber 100. Furthermore, oxygen concentration detectors 910 are installed in the processing gas exhaust ports 130, respectively, in order to monitor a starting point of the process using the oxygen concentration measured by the oxygen concentration detectors 910.

Here, the processing gas injection ports 123 are formed in an injection pipe 122 connected to a processing gas injection nozzle 121 to be aligned in the horizontal direction in the injection pipe 122. Accordingly, the processing gas injected from the processing gas injection nozzle 121 flows in the injection pipe 122, being lowered in injection pressure, and in this state, is injected through the plurality of processing gas injection ports 123, so that the processing gas can be uniformly distributed over the entire surface of the wafer. Furthermore, in order to ensure uniform distribution of the processing gas, a gas partition wall 124 is formed at the lateral wall of the chamber 100 against which the processing gas injected from the injection ports 123 collides. In order to allow a smooth exhaust of the processing gas injected from the processing gas injection ports 123 aligned in the horizontal direction, the chamber 100 is aligned with at least two processing gas exhaust ports 130, each of which has a diameter larger than that of the processing gas injection ports 123, on the lateral wall opposite to the lateral wall formed with the processing gas injection ports 123.

Meanwhile, after forming the wafer feeding passage 700 in one lateral wall of the chamber, the processing gas exhaust ports 121 may be formed on the lateral wall of the wafer feeding passage 700.

Referring to FIGS. 3, 4, and 7, for sealing between an outer peripheral surface of the quartz window 200 and a mounting portion of the chamber 100 at which the quartz is mounted, an O-ring 920 is interposed between the outer peripheral surface of the quartz window 200 and the mounting portion of the chamber 100.

The outer peripheral surface of the quartz window 200 consists of a combination of a tilt surface having a downwardly sloped outer surface, a perpendicular surface vertically extending from the lower end of the tilt surface, and a round surface having a curvature formed from the lower end of the perpendicular surface. Accordingly, the O-ring 920 is subjected to compression deformation due to a load from a protruded portion of the tilt surface, and thus forcibly seals the gap between the quartz window 200 and the chamber 100. With such a configuration for seal between the quartz window 200 and the chamber 100, if a portion of the quartz window 200 facing the wafer mounted in the chamber is broken or contaminated, the quartz window 200 is installed again in the chamber 100 after being flipped upside down, that is, the quartz window 200 is installed in the chamber 100 in a state shown in (2) of FIG. 7 wherein the quartz window 200 is installed in an inverted state, thereby maintaining the seal between the quartz window 200 and the chamber 100.

Referring to FIGS. 3, 4, and 8, the quartz window 200 has an area larger than that of the inner surface of the chamber 100, and a square shape, the edges of which oppose straight line portions of the inner surface of the chamber 100, respectively, while being positioned at the outside of the straight line portions. At this time, since each of regions 210 defined by the edges of the quartz window 200 and the straight line portions 112 of the inner surface of the chamber 100 is screened by the wall of the chamber 100, these regions are not influenced by thermal radiation emitted from the heat source. Accordingly, cooling water jackets 810 are installed in the chamber 100 to be positioned at a lower portion of the regions 210, cooling the quartz window 200 heated during the process, thereby preventing the quartz window from being broken. Meanwhile, the edges of the quartz 200 may be subjected to a rounding operation.

Referring to FIGS. 3, 4, 5, and 9, each of the edge ring-supports 300 comprises a rotational member 310 installed in the chamber 100 and having a rotational wing 311, a cylinder 320 connected to the rotational wing 311 and having a depression formed on the outer surface of the cylinder, a cylinder guide 330 with a protrusion engaged with the depression of the cylinder 320 and connecting the cylinder 320 to the rotational wing 311, and a cylinder guide-fixing pin 340 to fix the cylinder guide 330 to the rotational wing 310. The rotational wing 311 has a plurality of inverted triangular-shaped grooves formed on the upper surface thereof, so that the gas is prevented from flowing downward along the upper surface of the rotational wing 311. Stagnant gas in the inverted triangular-shaped grooves is lifted by heat generated during the rapid thermal processing. The inverted triangular-shaped grooves disperse thermal stress applied to the rotational wing 311 or thermal deformation of the rotational wing 311 caused by the thermal stress. Furthermore, since the cylinder 320 is connected to the rotational wing 311 by means of the double connection structure consisting of the cylinder guide 330 and the cylinder guide-fixing pin 340, the overall structure of the edge ring-supports 300 has a strong resistance to thermal deformation. The cylinder guide 330 and the cylinder guide-fixing pin 340 are made of a material having a strong resistance to thermal deformation.

Meanwhile, since the edge ring 400 and the edge ring-support 300 are located adjacent to the lateral wall of the chamber 100 according to the structure of the rapid thermal processing system, there is a problem of thermal deformation caused by their locations, and there is a need to forcibly cool these members after the process. According to the embodiment of the invention, in order to prevent the edge ring 400 and the edge ring-support 300 from being thermally deformed, and to forcibly cool these members after the process, a heating/cooling water-circulation passage 820 is provided in the inner wall of the chamber 100 such that the circulation passage 820 surrounds an outer peripheral surface of the edge ring 400 and a predetermined area of the edge ring-support 300. That is, since the temperatures of the edge ring 400 and the edge ring-support 300 are raised to a considerably high temperature during the process, the circulation passage 820 supplies heating water to prevent temperature variation, and supplies cooling water after the process, thereby rapidly cooling the edge ring 400 and the edge ring-support 300. Heating and cooling water supply ports 821 are inserted into the heating/cooling water-circulation passages 820 by an assembling force, respectively.

Due to the characteristics of the rapid thermal processing, the temperature of the chamber must be maintained within a predetermined range during the process, and the chamber must be forcibly cooled after the process. According to the embodiment of the present invention, a lower cooling system and an upper cooling system are implemented on the basis of a wafer mounting point for effective cooling.

Referring to FIGS. 3 and 5, the lower cooling system 830 comprises a first cooling gas injection part 831 provided on the bottom surface of the chamber 100, and one or more first cooling gas exhaust ports 832. The first cooling gas injection part 831 is provided, at the end thereof, with a plurality of injection holes radially arranged therein, and with a cap installed at an upper portion of the injection holes to define a predetermined space opened between the injection holes and the cap. Accordingly, the cooling gas injected from the first cooling gas injection part 831 is uniformly distributed over the bottom surface of the chamber 100 by mean of the cap, mainly cooling the bottom surface of the chamber 100, and is then exhausted through the first cooling gas injection parts 831.

Meanwhile, when the wafer is fed into the chamber 100, oxygen also flows in the chamber 100, and is then removed using a purge gas after the wafer is mounted on the edge ring 400. However, gas does not smoothly flow under the wafer, for instance, on the bottom surface of the chamber 100, and thus some amount of oxygen remains there, having a negative influence on the results of the process. Accordingly, in the embodiment of the present invention, the first cooling gas exhaust parts 831 are positioned at the opposite side of the wafer feeding passage 700, and the purge gas is supplied into the chamber 100 through the first cooling gas exhaust part 831, removing oxygen remaining under the wafer.

In order to enhance the cooling efficiency while maximally utilizing the components of the rapid thermal processing system according the embodiment of the present invention, the upper cooling system is comprised of a primary cooling system for directly cooling the lateral wall of the chamber and providing a cooling gas atmosphere in the chamber, and with a secondary cooling system for directly further cooling the lateral wall.

Referring to FIGS. 3 and 6, one or more cooling gas injection parts (which will be referred to as second cooling gas injection part, 841) of the upper primary cooling system are formed in the chamber 100, and spaced a predetermined distance from the processing gas injection ports 123, such that the cooling gas is injected over the wafer mounting point. The second cooling gas injection parts 841 are separated from the processing gas injection ports 123 such that flow of the cooling gas and flow of the processing gas do not influence each other. At this time, although the cooling gas, having flowed in the chamber 100 through the second cooling gas injection part 841, generally lowers the temperature inside the chamber 100, it is desirable that some portions of the cooling gas flow along the lateral wall of the chamber 100 in order to maximize the cooling efficiency. For this purpose, each of the second cooling gas injection part 841 has an injection end with a gentle slope formed at a predetermined region thereof such that some portions of the cooling gas being injected into the chamber 100 can flow along the lateral wall of the chamber 100, and with a steep slope formed at a rest region of the injection end such that the cooling gas being injected can flow in the chamber 100. The cooling gas having flowed into the chamber 100 through the second cooling gas injection parts 841 is exhausted through the processing gas exhaust parts 130.

Referring to FIGS. 3, 8, and 9, the upper secondary cooling system 850 uses the heating/cooling water-circulation passage 820 as described above. The secondary cooling system 850 comprises one or more cooling gas injection parts 851 and one or more cooling gas exhaust parts 852 (which will be referred to as a third cooling gas injection part and a third cooling gas exhaust part). With regard to this, a groove 822, formed around an outer surface of the cooling/heating water-circulation passage 820, is formed to define a cooling gas passage between the outer surface of the cooling/heating water-circulation passages 820 and the inner wall of the chamber 100. The third cooling gas injection part 851 and the cooling gas exhaust part 852 communicate with the groove 822, respective. Accordingly, the cooling gas injected from the third cooling gas injection part 851 directly cools the lateral wall of the chamber 100 while flowing along the heating/cooling water-circulation passage 820, and is then exhausted through the third cooling gas exhaust part 852.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A rapid thermal processing system, comprising: a chamber provided at a lateral wall of the chamber with one or more processing gas injection ports and at the opposite lateral wall thereof with one or more processing gas exhaust ports; a heat source installed in the chamber for heating a wafer; a quartz window mounted on the chamber such that the quartz window can be located below the heat source; an edge ring-support installed in the chamber such that edge ring-support can be located below the quartz window; and an edge ring equipped on the edge ring-support for mounting the wafer,
wherein the chamber has an inner surface with a cross-section in a multi-line shape consisting of a plurality of arcs separated from each other and having the same radius and the same center and a plurality of straight lines connecting the arcs to each other.

2. The rapid thermal processing system as set forth in claim 1, wherein each of the arcs has a central angle of 15-50°.

3. The rapid thermal processing system as set forth in claim 1, wherein an O-ring is interposed between an outer peripheral surface of the quartz window and a mounting portion of the chamber at which the quartz window is mounted.

4. The rapid thermal processing system as set forth in claim. 3, wherein the outer peripheral surface of the quartz window consists of a combination of a tilt surface, a perpendicular surface, and a round surface.

5. The rapid thermal processing system as set forth in claim 1, wherein the quartz window has an area larger than that of the inner surface of the chamber, and a square shape having edges, each opposing the straight line portion of the inner surface of the chamber while being positioned at the outside of the straight line portion; and
wherein the rapid thermal processing system further comprises one or more cooling water jackets, each being installed in the chamber such that the cooling water jacket can be positioned at a lower portion of a region defined by the edge of the quartz window and the straight line portion of the inner surface of the chamber.

6. The rapid thermal processing system as set forth in claim 1, wherein the chamber is formed at one lateral wall thereof with an injection pipe connected to a processing gas injection nozzle and having the processing gas injection ports aligned in the injection pipe, and each of the processing gas exhaust ports is formed with at least two exhaust ports aligned in the processing gas exhaust port and having a diameter larger that of the processing gas injection port.

7. The rapid thermal processing system as set forth in claim 1, wherein each of the processing gas exhaust ports is provided with an oxygen concentration detector.

8. The rapid thermal processing system as set forth in claim 1, wherein the chamber is formed with a wafer feeding passage in the lateral wall of the chamber, and the processing gas injection nozzle connected to the processing gas injection ports are formed on a lateral wall of the wafer feeding passage.

9. The rapid thermal processing system as set forth in claim 1, wherein the edge ring-support comprises: a rotational member installed in the chamber and having a rotational wing with a groove formed on an upper surface of the rotational wing; a cylinder connected to the rotational wing and mounting the edge ring on an upper surface of the cylinder; a cylinder guide engaged with the cylinder; and a cylinder guide-fixing pin for fixing the cylinder guide to the rotational wing.

10. The rapid thermal processing system as set forth in claim 1, further comprising a cooling/heating water-circulation passage provided in an inner wall of the chamber such that the circulation passage surrounds an outer peripheral surface of the edge ring and a predetermined area of the edge ring-support.

11. The rapid thermal processing system as set forth in claim 1, further comprising: a first cooling gas injection part for injecting a cooling gas into the chamber; and a first cooling gas exhaust part for exhausting the cooling gas exhausted from the first cooling gas inject part to the outside of the chamber, the first cooling gas injection part and the first cooling gas exhaust part being installed on the bottom surface of the chamber.

12. The rapid thermal processing system as set forth in claim 11, wherein the first cooling gas injection part comprises a plurality of injection holes radially arranged therein, and a cap installed at an upper portion of the injection holes to define a predetermined space opened between the injection holes and the cap.

13. The rapid thermal processing system as set forth in claim 1, further comprising a second cooling gas injection part, formed on the lateral wall of the chamber while being spaced from the processing gas inject ports, for injecting the cooling gas over the wafer mounted on the edge ring, and having an injection end with a gentle slope formed at a predetermined region of the injection end, such that a portion of the cooling gas being injected can flow along the lateral wall of the chamber, and with a steep slope formed at a rest region of the injection end.

14. The rapid thermal processing system as set forth in claim 10, wherein the cooling/heating water-circulation passage has a groove formed around an outer surface of the cooling/heating water-circulation passage facing the inner wall of the chamber, and the rapid thermal processing system may further comprise a third cooling gas injection part and a third cooling gas exhaust part installed in the chamber being connected to the groove, respectively.
